(19) United States
(12) Patent Application Publication
(10) Pub. No.: US 2025/0054902 A1
(43) Pub. Date: Feb. 13, 2025

(54) Semiconductor Device and Method Using Lead Frame Interposer in Bump Continuity Test

(71) Applicant: STATS ChipPAC Pte. Ltd., Singapore (SG)

(72) Inventor: Peik Eng Ooi, Singapore (SG)

(73) Assignee: STATS ChipPAC Pte. Ltd., Singapore (SG)

(21) Appl. No.: 18/448,913

(22) Filed: Aug. 12, 2023

(51) Int. Cl. H01L 23/00; H01L 23/495

(52) U.S. Cl. CPC H01L 24/49; H01L 23/49503; H01L 24/48; H01L 24/85; H01L 2224/48175; H01L 2224/4845; H01L 2224/49112; H01L 2224/85365

(57) ABSTRACT

A semiconductor device has an electrical component with bump structures. A conductive layer is formed over the electrical component with a first segment of the conductive layer coupled between the first and second bumps. The electrical component is disposed on a paddle of a lead frame interposer. A first bond wire is coupled between a first lead and the first bump. A second bond wire is coupled between a second lead and the second bump. A third bond wire is coupled between a third lead and a third bump, and a fourth bond wire is coupled between a fourth lead and a fourth bump. A fifth bond wire coupled between the second lead and third lead and a second segment of the conductive layer is coupled between the third bump and fourth bump to constitute a daisy chain loop to test continuity of the bump structures.

### FIELD OF THE INVENTION

The present invention relates in general to semiconductor devices and, more particularly, to a semiconductor device and method of using a lead frame interposer for a bump continuity test for a WLCSP.

### BACKGROUND OF THE INVENTION

Semiconductor devices are commonly found in modern electrical products. Semiconductor devices perform a wide range of functions, such as signal processing, high-speed calculations, transmitting and receiving electromagnetic signals, controlling electrical devices, photo-electric, and creating visual images for television displays. Semiconductor devices are found in the fields of communications, power conversion, networks, computers, entertainment, and consumer products. Semiconductor devices are also found in military applications, aviation, automotive, industrial controllers, and office equipment.

Semiconductor devices often contain a semiconductor die or substrate with electrical interconnect structures, e.g., redistribution layers (RDL) formed over one or more surfaces of the semiconductor die or substrate to perform necessary electrical functions. A plurality of bumps is formed on a surface of the semiconductor die while in wafer form for external electrical interconnect with the RDL. The bumps should be tested for electrical continuity to identify defects and provide a known good die. The bump continuity test is particularly challenging for fine pitch bumps, e.g., about 40.0 micrometers (μm) or greater.

### BRIEF DESCRIPTION OF THE DRAWINGS

FIGS. 1a-1i illustrate a semiconductor wafer with a plurality of semiconductor die with bump structures;

FIGS. 2a-2c illustrate forming conductive segments on a surface of the semiconductor die between pairs of bump structures;

FIGS. 3a-3b illustrate forming conductive segments on the surface of the semiconductor die prior to forming the bump structures;

FIGS. 4a-4c illustrate a lead frame interposer;

FIGS. 5a-5e illustrate the lead frame interposer with an electrical component disposed on the paddle and bond wires connecting the leads to the bump structures;

FIG. 6 illustrates an electrical continuity test of the bump structures using the bond wires and conductive segment;

FIGS. 7a-7c illustrate the electrical continuity test in a daisy chain loop arrangement;

FIG. 8 illustrates the bump structures of the electrical component logically arranged in regions for the electrical continuity test;

FIG. 9 illustrates a daisy chain loop electrical continuity test for a smaller electrical component;

FIG. 10 illustrates cutting the conductive segments post electrical continuity test;

FIG. 11 illustrates the electrical continuity test using RDL of the electrical component; and

FIG. 12 illustrates a printed circuit board (PCB) with different types of packages disposed on a surface of the PCB.

### DETAILED DESCRIPTION OF THE DRAWINGS

The present invention is described in one or more embodiments in the following description with reference to the figures, in which like numerals represent the same or similar elements. While the invention is described in terms of the best mode for achieving the invention's objectives, it will be appreciated by those skilled in the art that it is intended to cover alternatives, modifications, and equivalents as may be included within the spirit and scope of the invention as defined by the appended claims and their equivalents as supported by the following disclosure and drawings. The features shown in the figures are not necessarily drawn to scale. Elements having a similar function are assigned the same reference number in the figures. The term “semiconductor die” as used herein refers to both the singular and plural form of the words, and accordingly, can refer to both a single semiconductor device and multiple semiconductor devices.

Semiconductor devices are generally manufactured using two complex manufacturing processes: front-end manufacturing and back-end manufacturing. Front-end manufacturing involves the formation of a plurality of die on the surface of a semiconductor wafer. Each die on the wafer contains active and passive electrical components, which are electrically connected to form functional electrical circuits. Active electrical components, such as transistors and diodes, have the ability to control the flow of electrical current. Passive electrical components, such as capacitors, inductors, and resistors, create a relationship between voltage and current necessary to perform electrical circuit functions.

Back-end manufacturing refers to cutting or singulating the finished wafer into the individual semiconductor die and packaging the semiconductor die for structural support, electrical interconnect, and environmental isolation. To singulate the semiconductor die, the wafer is scored and broken along non-functional regions of the wafer called saw streets or scribes. The wafer is singulated using a laser cutting tool or saw blade. After singulation, the individual semiconductor die are disposed on a package substrate that includes pins or contact pads for interconnection with other system components. Contact pads formed over the semiconductor die are then connected to contact pads within the package. The electrical connections can be made with conductive layers, bumps, stud bumps, conductive paste, or wirebonds. An encapsulant or other molding material is deposited over the package to provide physical support and electrical isolation. The finished package is then inserted into an electrical system and the functionality of the semiconductor device is made available to the other system components.

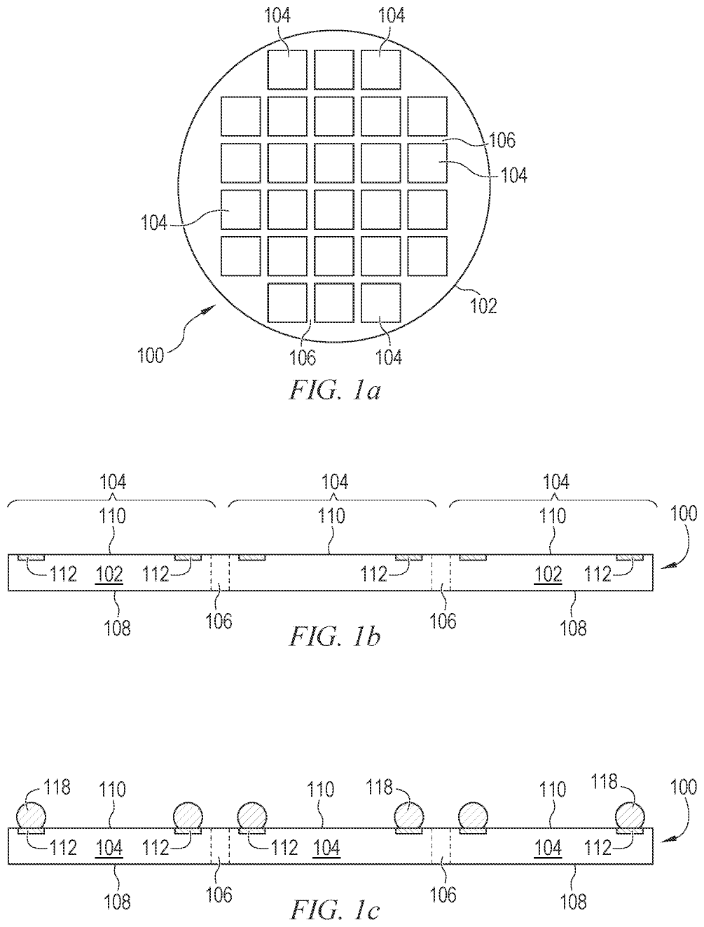

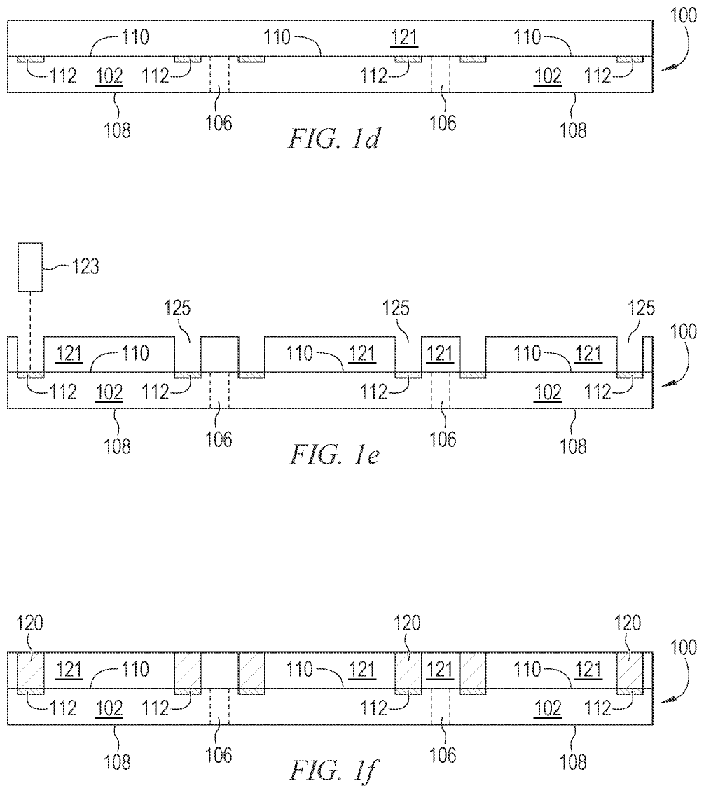

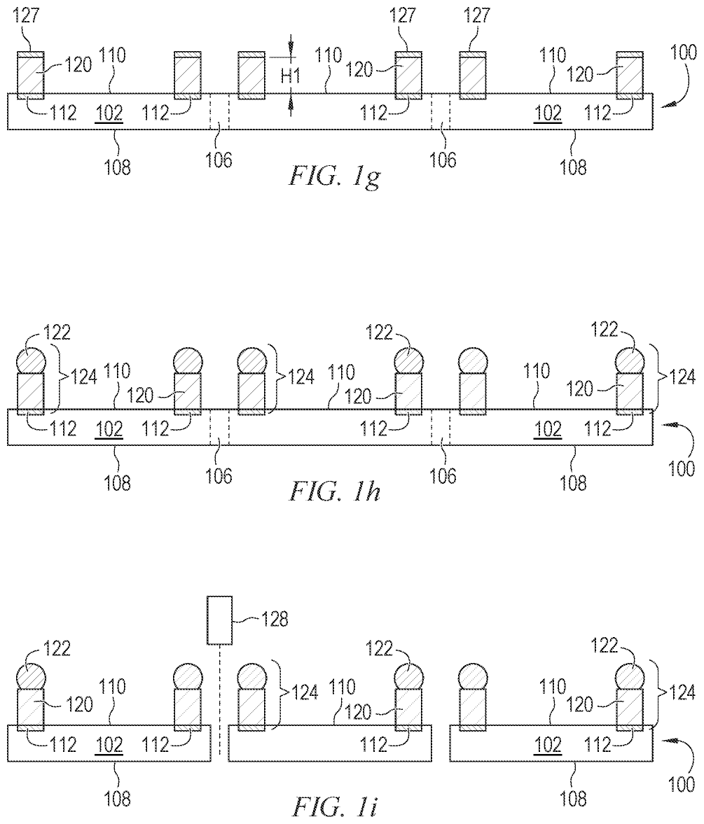

FIG. 1a shows a semiconductor wafer 100 with a base substrate material 102, such as silicon, germanium, aluminum phosphide, aluminum arsenide, gallium arsenide, gallium nitride, indium phosphide, silicon carbide, or other bulk material for structural support. A plurality of semiconductor die or electrical components 104 is formed over wafer 100 separated by a non-active, inter-die wafer area or saw street 106. Saw street 106 provides cutting areas to singulate semiconductor wafer 100 into individual semiconductor die 104. In one embodiment, semiconductor wafer 100 has a width or diameter of 100-450 millimeters (mm).

FIG. 1b shows a cross-sectional view of a portion of semiconductor wafer 100. Each semiconductor die 104 has a back or non-active surface 108 and an active surface 110 containing analog or digital circuits implemented as active devices, passive devices, conductive layers, and dielectric layers formed within the die and electrically interconnected according to the electrical design and function of the die. For example, the circuit may include one or more transistors, diodes, and other circuit elements formed within active surface 110 to implement analog circuits or digital circuits, such as digital signal processor (DSP), application specific integrated circuits (ASIC), memory, or other signal processing circuit. Semiconductor die 104 may also contain IPDs, such as inductors, capacitors, and resistors, for RF signal processing. Semiconductor die 104 on wafer 100 are considered a wafer level chip scale package (WLCSP).

An electrically conductive layer 112 is formed over active surface 110 using PVD, CVD, electrolytic plating, electroless plating process, or other suitable metal deposition process. Conductive layer 112 can be one or more layers of aluminum (Al), copper (Cu), tin (Sn), nickel (Ni), gold (Au), silver (Ag), or other suitable electrically conductive material. Conductive layer 112 operates as contact pads electrically connected to the circuits on or within active surface 110.

In FIG. 1c, an electrically conductive bump material is deposited over conductive layer 112 using an evaporation, electrolytic plating, electroless plating, ball drop, or screen printing process. The bump material can be Al, Sn, Ni, Au, Ag, Pb, Bi, Cu, solder, and combinations thereof, with an optional flux solution. For example, the bump material can be eutectic Sn/Pb, high-lead solder, or lead-free solder. The bump material is bonded to conductive layer 112 using a suitable attachment or bonding process. In one embodiment, the bump material is reflowed by heating the material above its melting point to form balls or bumps 118. In one embodiment, bump 118 is formed over an under bump metallization (UBM) having a wetting layer, barrier layer, and adhesive layer. Bump 118 can also be compression bonded or thermocompression bonded to conductive layer 112. Bump 118 represents one type of interconnect structure that can be formed over conductive layer 112. The interconnect structure can also use bond wires, conductive paste, stud bump, micro bump, or other electrical interconnect. Bump 118 is a type of bump structure. Bumps 118 have a fine bump pitch, i.e., 40.0 micrometers (μm) or more.

In another embodiment of forming a bump structure, continuing from FIG. 1b, a solder resist or photoresist layer 121 is formed over active surface 110, as shown in FIG. 1d. In FIG. 1e, a plurality of openings 125 is formed in solder resist/photoresist 121 using an etching process or laser direct ablation (LDA) by way of laser 123.

In FIG. 1f, openings 125 are filled with conductive material to form conductive columns or pillars or posts 120. In FIG. 1g, the remaining solder resist/photoresist 121 is removed leaving conductive columns or pillars or posts 120. Conductive columns or pillars or posts 120 can be Al, Cu, Sn, Ni, Au, Ag, multi-layer combined or other suitable electrically conductive material. Conductive pillars 120 can have a height Hi of 35.0 μm to compensate for thickness variation in different technologies, such as surface mount and flipchip. In one embodiment, conductive pillars 120 may have Cu organic solderability preservative (OSP), or electroless-nickel electroless-palladium immersion gold (ENEPIG), or electroless nickel immersion gold (ENIG), or immerging tin, or solder cap finish or layer 127 formed on exposed pads or metal surfaces.

In FIG. 1h, an electrically conductive bump material is deposited over conductive pillar 120 using an evaporation, electrolytic plating, electroless plating, ball drop, or screen printing process. The bump material can be Al, Sn, Ni, Au, Ag, Pb, Bi, Cu, solder, and combinations thereof, with an optional flux solution. For example, the bump material can be eutectic Sn/Pb, high-lead solder, or lead-free solder. The bump material is bonded to conductive pillar 120 using a suitable attachment or bonding process. In one embodiment, the bump material is reflowed by heating the material above its melting point to form balls or bumps 122. Solder cap finish or layer 127 will dissolve with the formation of bumps 122. In another embodiment, bump 122 is formed over a UBM having a wetting layer, barrier layer, and adhesive layer. Bump 122 can also be compression bonded or thermocompression bonded to conductive pillar 120. Bump 122 represents one type of interconnect structure that can be formed over conductive pillar 120. The interconnect structure can also use conductive paste, stud bump, micro bump, or other electrical interconnect. The combination of conductive pillar 120 and bump 122 constitutes bump structure 124. Bump structures 124 have a fine bump pitch, i.e., 40.0 μm or more.

In FIG. 1i, semiconductor wafer 100 is singulated through saw street 106 using a saw blade or laser cutting tool 128 into individual semiconductor die 104. The individual semiconductor die 104 can be inspected and electrically tested for identification of known good die or known good unit (KGD/KGU) post singulation. A similar singulation would occur for FIG. 1c to extract individual semiconductor die 104 with bumps 118.

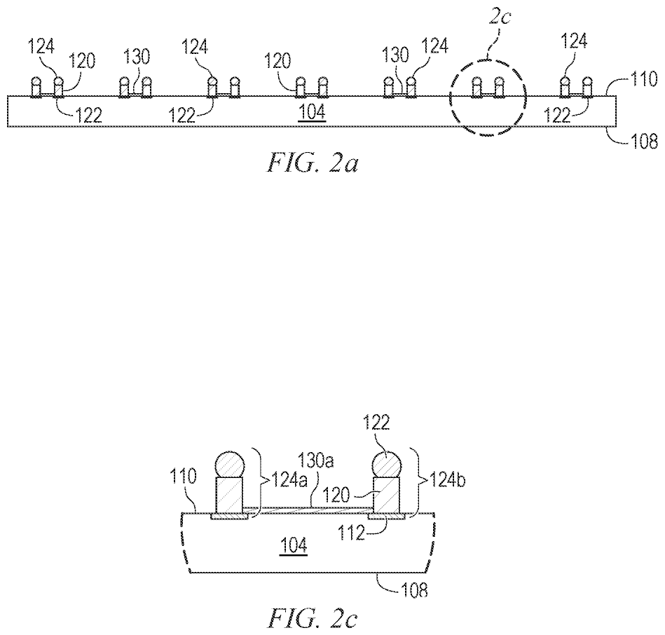

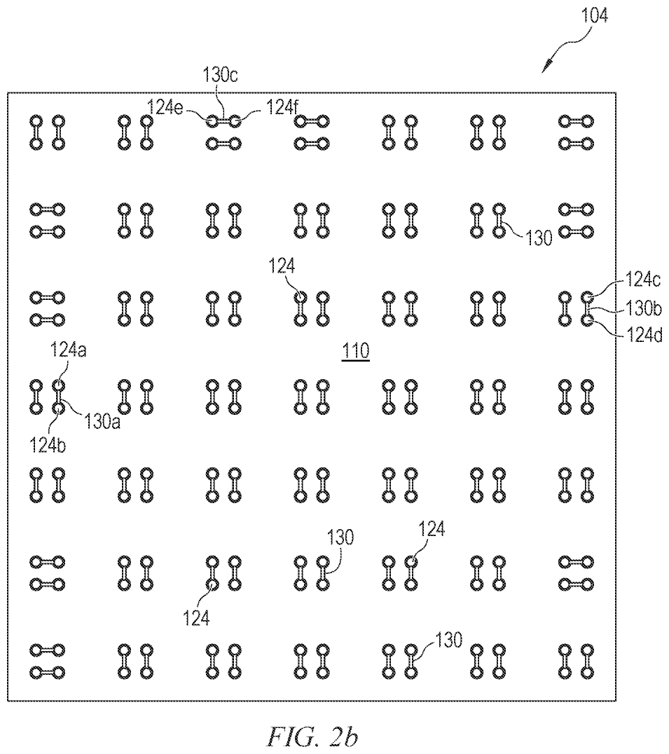

FIG. 2a illustrates a cross-sectional view of semiconductor die 104 with a plurality of bump structures 124 formed over active surface 110. FIG. 2b is a top view of semiconductor die 104 with a plurality of bump structures 124 formed over active surface 110. While the remaining disclosure is directed to bump structures 124 from FIGS. 1h-1i, the discussion is applicable to bumps 118 from FIG. 1c.

Conductive layer 130 is formed over active surface 110 using PVD, CVD, electrolytic plating, electroless plating process, or other suitable metal deposition process. Conductive layer 130 can be one or more layers of Al, Cu, Sn, Ni, Au, Ag, or other suitable electrically conductive material. In particular, portions or segments of conductive layer 130 are electrically and mechanically connected between pairs of bump structures 124. For example, conductive segment 130a is mechanically and electrically coupled between bump structures 124a and 124b. Conductive segment 130b is mechanically and electrically coupled between bump structures 124c and 124d. Conductive segment 130c is mechanically and electrically coupled between bump structures 124e and 124f. Each pair of bump structures 124 would have a corresponding conductive segment 130, as shown in FIG. 2b. Otherwise, the plurality of conductive segments 130 is physically and electrically isolated. In other words, bump structures 124a and 124b are connected by conductive segment 130a, bump structures 124c and 124d are connected by conductive segment 130b, and bump structures 124e and 124f are connected by conductive segment 130c. However, bump structures 124a and 124b are physically and electrically isolated from bump structures 124c and 124d, and bump structures 124c and 124d are physically and electrically isolated from bump structures 124e and 124f, at least with respect to conductive segments 130a-130c. Conductive segment 130a is physically and electrically isolated from conductive segment 130b, and conductive segment 130b is physically and electrically isolated from conductive segment 130c. The pairs of bump structures can be adjacent or separated in or by a pattern, e.g., on a diagonal or alternating pattern.

FIG. 2c shows further detail of a portion of semiconductor die 104 with adjacent pair of bump structures 124a and 124b and interconnecting conductive segment 130a. Conductive segment 130a physically and electrically contacts a bottom portion of conductive pillar 120 of each bump structure of the pair of bump structures 124a and 124b, as well as conductive layer 112. That is, one end of conductive segment 130a is connected to a bottom portion of conductive pillar 120 of bump structure 124a, as well as conductive layer 112 under bump structure 124a. A distal end of conductive segment 130a is connected to a bottom portion of conductive pillar 120 of bump structure 124b, as well as conductive layer 112 under bump structure 124b. Conductive segment 130a provides an electrical path between bump structures 124a and 124b. In a similar manner, conductive segment 130b provides an electrical path between bump structures 124c and 124d, and conductive segment 130c provides an electrical path between bump structures 124e and 124f.

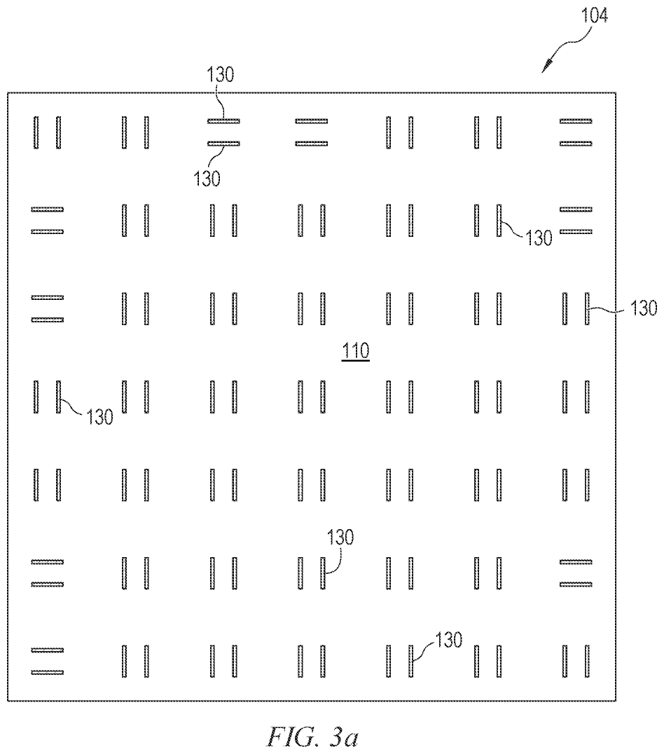

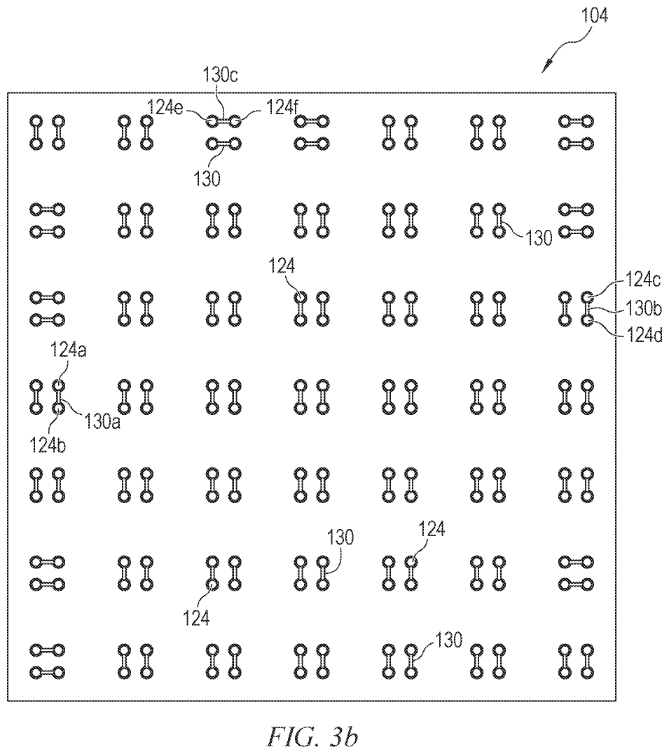

In another embodiment, conductive layer 130 is formed over active surface 110 of semiconductor die 104 as a WLCSP, prior to forming bump structures 124. FIG. 3a shows conductive layer 130 formed over active surface 110, absent the bump structures. After forming conductive layer 130, bump structures 124 would be formed, similar to FIGS. 1d-1i, as shown in FIG. 3b. Bump structures 124 make physical and electrical connection to the corresponding conductive segments 130.

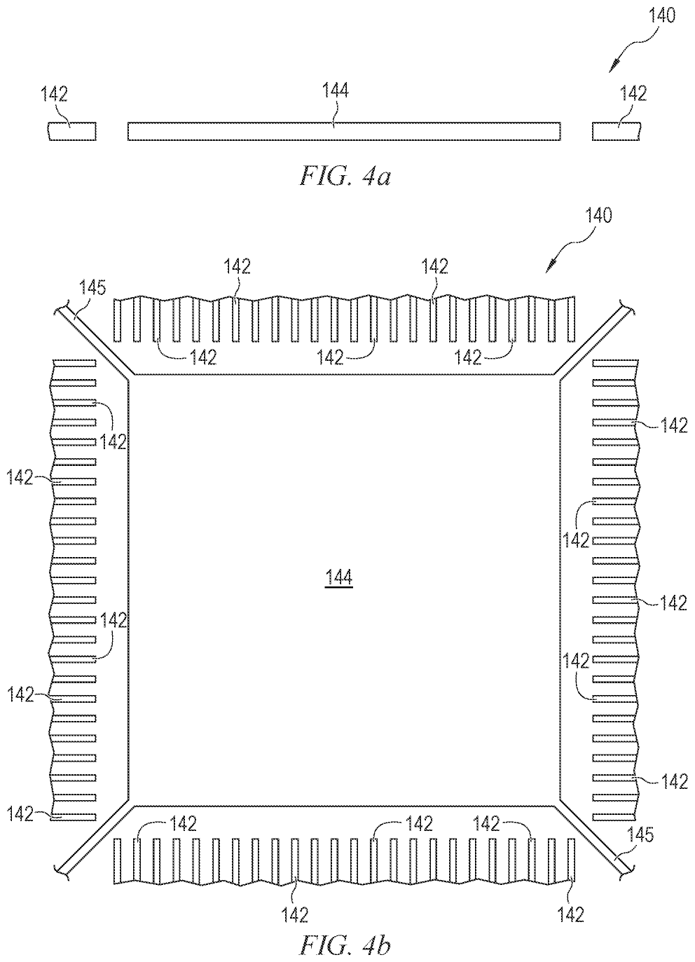

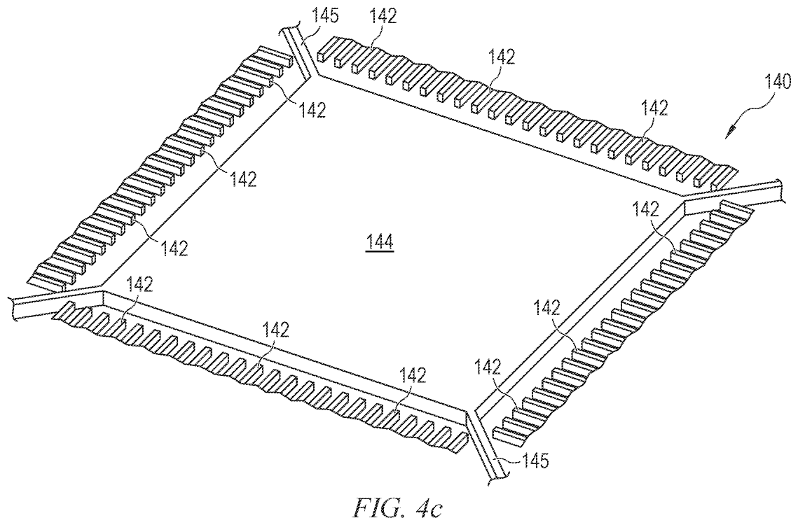

FIGS. 4a-4c illustrate a lead frame interposer 140. In one embodiment, lead frame interposer 140 is an etched quad flat no-lead (QFN) frame. FIG. 4a is a cross-sectional view of lead frame interposer 140 with leads 142 and flag or paddle 144. FIG. 4b is a top view of lead frame interposer 140 with leads 142 and flag or paddle 144 and flag or paddle supports 145. FIG. 4c is a perspective view of lead frame interposer 140 with leads 142 and flag or paddle 144 and flag or paddle supports 145. As is well known, leads 142 and paddle supports 145 would connect to a perimeter frame (not shown).

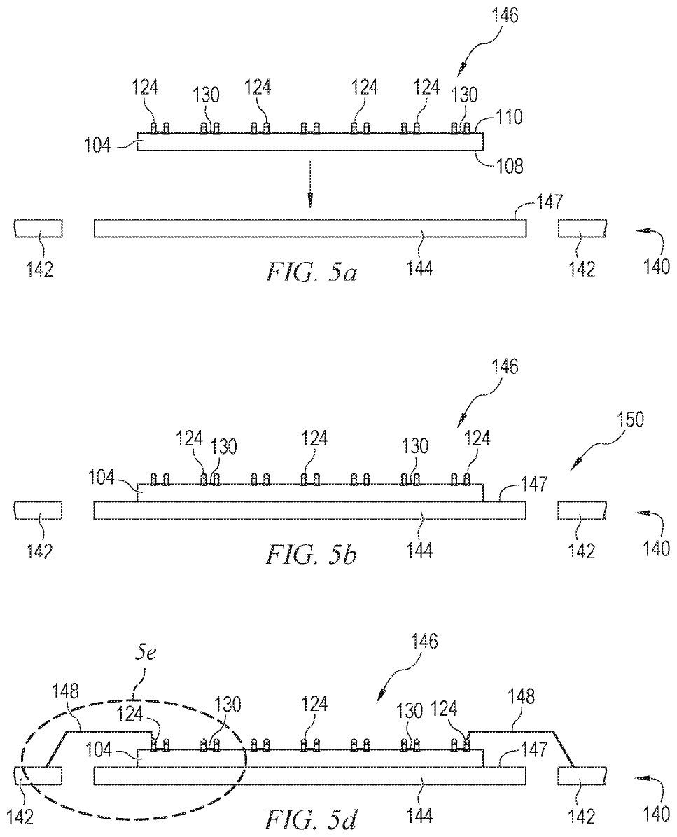

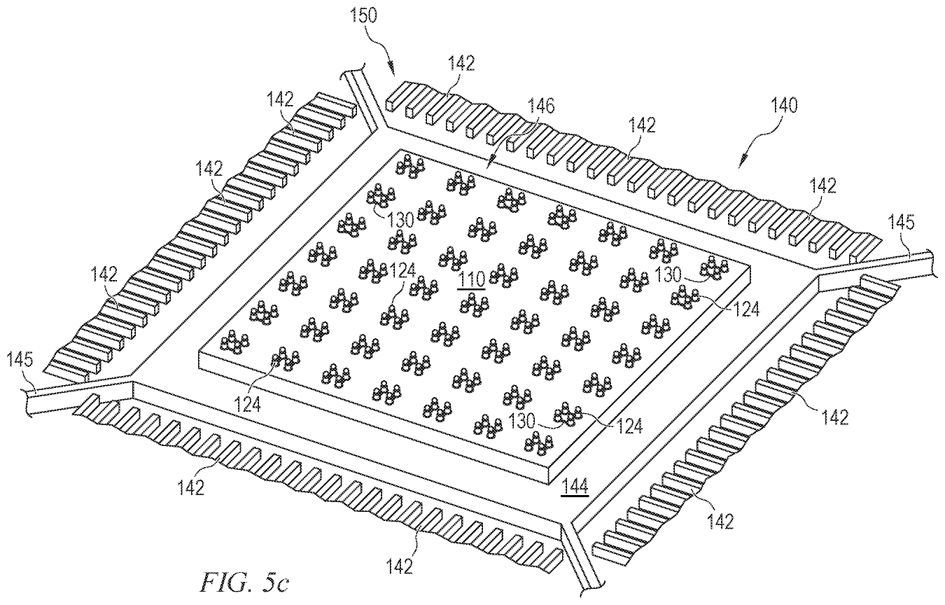

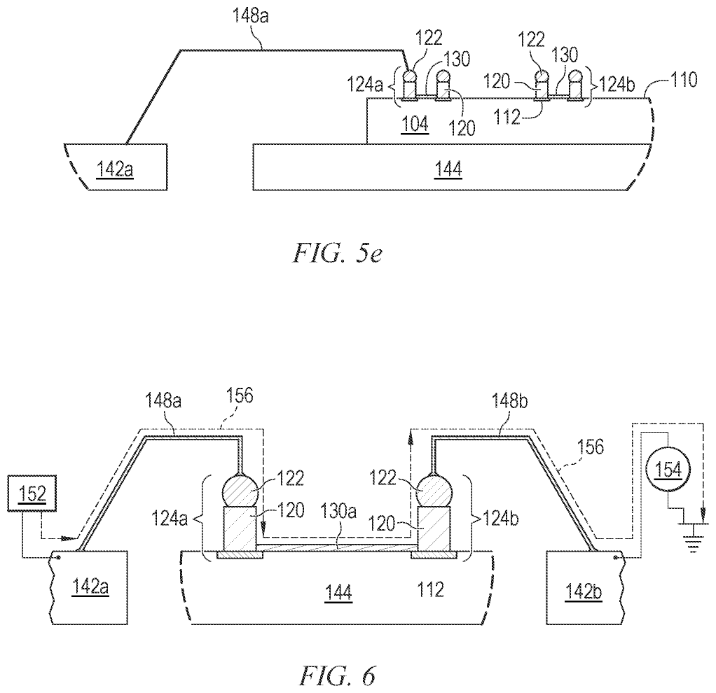

In FIG. 5a, electrical component 146 is disposed over surface 147 of paddle 144 of lead frame interposer 140. Electrical component 146 can be semiconductor die 104 from FIG. 2a with back surface 108 oriented toward surface 147 of paddle 144. Alternatively, electrical component 146 can include other semiconductor die, semiconductor packages, surface mount devices, RF components, discrete electrical devices, or integrated passive devices (IPD).

Electrical component 146 is positioned over paddle 144 using a pick and place operation. Electrical component 146 is brought into contact with paddle 144 and secured with an adhesive or other bonding layer. FIG. 5b illustrates electrical component 146 bonded to paddle 144, as assembly 150. FIG. 5c is a perspective view of assembly 150 with electrical component 146 bonded to paddle 144 of lead frame interposer 140.

In FIG. 5d, a plurality of bond wires 148 is connected between leads 142 and bump structures 124. In particular, bond wire 148 attaches to a top surface of bump 122. Bond wire 148 can take a variety of forms including ball-on-stich security bump (BSB), stud stitch bond (SSB), ball bond, and reverse stand-off stitch bonding (RSSB).

FIG. 5e shows further detail of a first end of bond wire 148a electrically and mechanically connected to a surface of lead 142a, and a second distal end of bond wire 148a electrically and mechanically connected to a top surface of bump 122 of bump structure 124a.

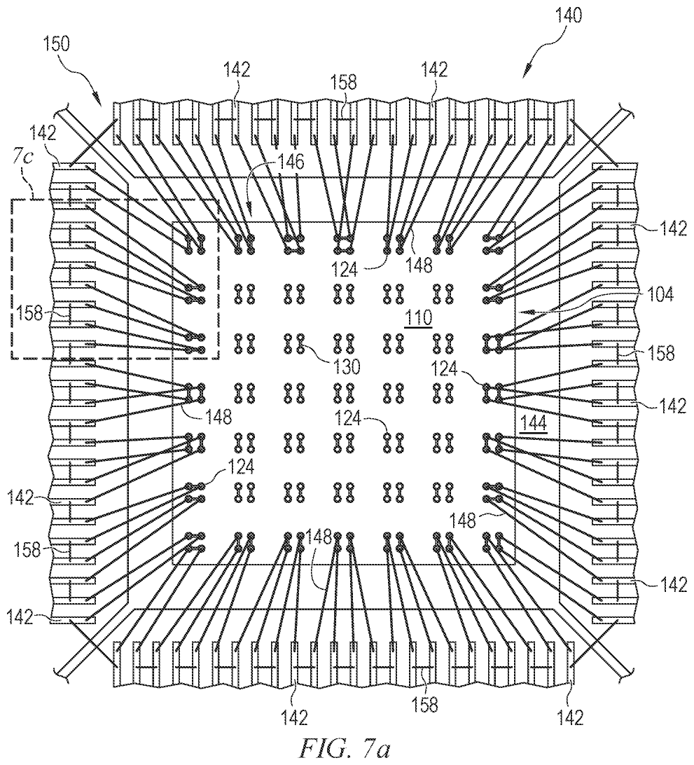

Lead frame interposer 140, bond wires 148, and conductive segments 130 are used in a daisy chain loop for a bump continuity test of bump structures 124 or bumps 118. FIG. 6 illustrates further detail of the bump continuity test. In a simplified explanation, lead 142a connects to bump 122 of bump structure 124a with bond wire 148a. Conductive pillar 120 of bump structure 124a is connected to conductive pillar 120 of bump structure 124b with conductive segment 130a. Bump 122 of bump structure 124b connects to lead 142b with bond wire 148b. A voltage source 152 is applied to lead 142a. A current measuring device or instrument 154 is coupled to lead 142b. If there is continuity, a current will flow along conduction path 156 from voltage source 152 through lead 142a, bond wire 148a, bump 122 of bump structure 124a, conductive pillar 120 of bump structure 124a, conductive segment 130a, conductive pillar 120 of bump structure 124b, bump 122 of bump structure 124b, bond wire 148b, and lead 142b to current measuring device or instrument 154. If bump structures 124a and 124b have electrical continuity, then a current will be detected by current measuring device or instrument 154 and the bump continuity test is considered a pass. If no current is detected, the assumption is that an electrical discontinuity may exist in bump structures 124a and/or 124b. A failure analysis can be conducted, rework can take place if indicated, and re-test of bump continuity.

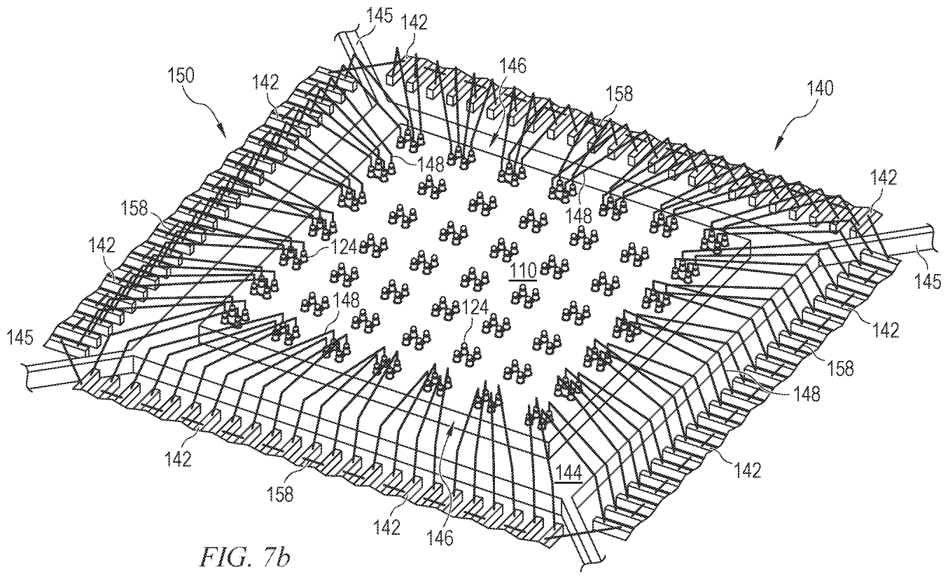

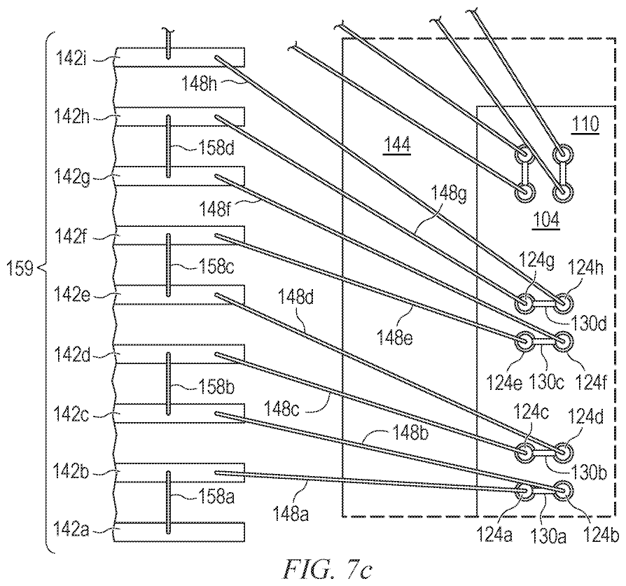

The bump continuity test can be expanded to use more leads 142 and more bond wires 148 to simultaneously test multiple pairs of bumps structures 124. In FIG. 7a, bump structures 124 are serially connected or arranged in a daisy chain loop with bond wires 148 to leads 142 to conduct a bump continuity test on a plurality of pairs of bump structures 124, simultaneously. FIG. 7b is a perspective view of the daisy chain loop with bond wires 148 to leads 142 to conduct a bump continuity test on a plurality of pairs of bump structures 124, simultaneously.

FIG. 7c shows further detail of a portion of lead frame interposer 140 and electrical component 146 to conduct a bump continuity test on a plurality of pairs of bump structures 124 using daisy change loop 159 including leads 142, bond wires 148, and conductive segments 130. Daisy chain loop 159 can continue completely around lead frame interposer 140. Assume voltage source 152 is coupled to lead 142a. Bond wires 158 are coupled between alternating and adjacent leads extending the daisy chain loop. For example, bond wire 158a is coupled between lead 142a and lead 142b. The combination of lead 142a, bond wire 158a, lead 142b, bond wire 148a, bump structure 124a, conductive segment 130a, bump structure 124b, bond wire 148b, lead 142c, bond wire 158b, lead 142d, bond wire 148c, bump structure 124c, conductive segment 130b, bump structure 124d, bond wire 148d, lead 142e, bond wire 158c, lead 142f, bond wire 148e, bump structure 124e, conductive segment 130c, bump structure 124f, bond wire 148f, lead 142g, bond wire 158d, lead 142h, bond wire 148g, bump structure 124g, conductive segment 130d, bump structure 124h, bond wire 148h, and lead 142i constitutes daisy chain loop 159, which can be continued or repeated around lead frame interposer 140.

If there is continuity, a current will pass from voltage source 152 through lead 142a, bond wire 158a, lead 142b, bond wire 148a, bump structure 124a, conductive segment 130a, bump structure 124b, bond wire 148b, and lead 142c. The current will continue and pass through bond wire 158b, lead 142d, bond wire 148c, bump structure 124c, conductive segment 130b, bump structure 124d, bond wire 148d, and lead 142e. The current will continue and pass through bond wire 158c, lead 142f, bond wire 148e, bump structure 124e, conductive segment 130c, bump structure 124f, bond wire 148f, and lead 142g. The current will continue and pass through bond wire 158d, lead 142g, bond wire 158d, lead 142h, bond wire 148g, bump structure 124g, conductive segment 130d, bump structure 124h, bond wire 148h, and lead 142i. The daisy-chain loop 159 can continue completely around lead frame interposer 140, for any number of bump structures 124, or until there are no more available leads 142 on lead frame interposer 140.

As in FIG. 6, if bump structures 124a-124h in FIG. 7c, and more bump structures 124 in FIGS. 7a-7b, have electrical continuity, then a current will be detected by current measuring device or instrument 154 and the bump continuity test is considered a pass. If no current is detected, the assumption is that an electrical discontinuity may exist in one or more bump structures 124a-124h, or more bump structures 124 in FIGS. 7a-7b. Electrical component 146 fails continuity test. A failure analysis can be conducted, rework can take place if indicated, and re-test of bump continuity performed.

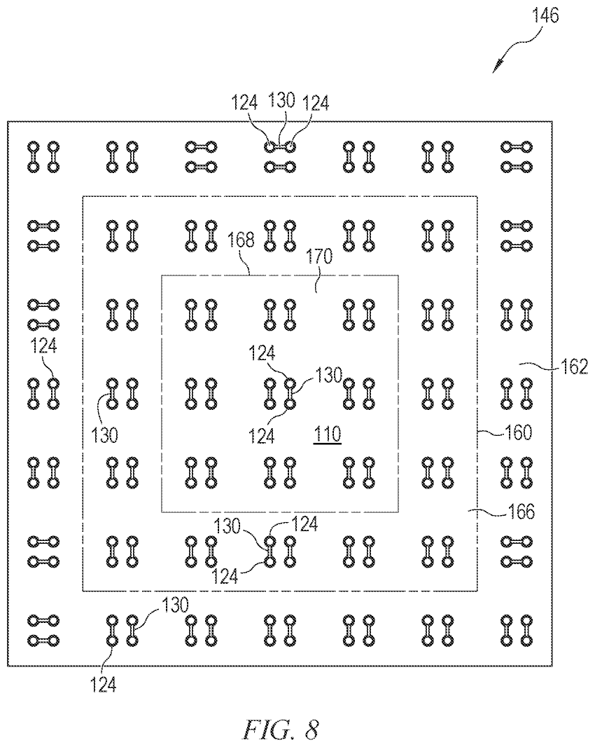

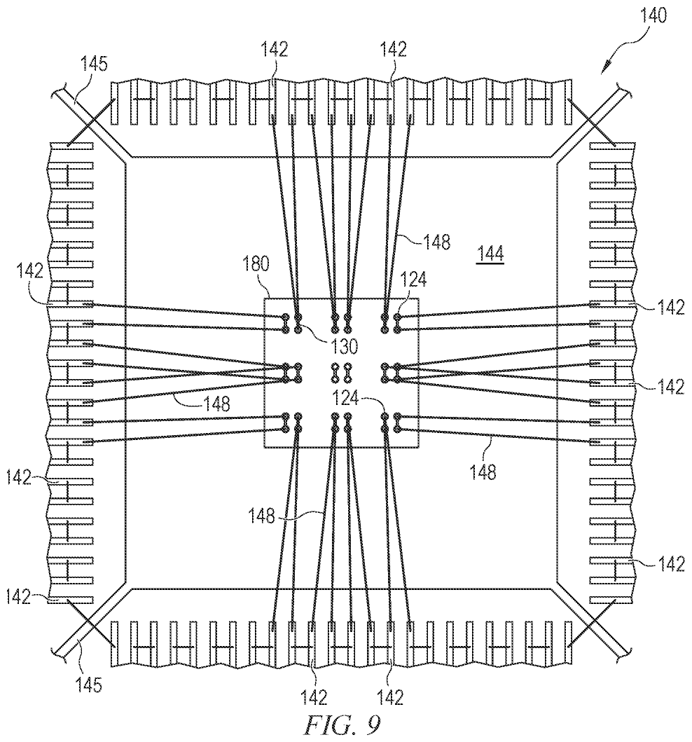

In the event there are more bump structures 124 on electrical component 146 than available leads 142 on lead frame interposer 140, then electrical component 146 can be logically organized into zones or regions. In FIG. 8, electrical component 146 is organized so that region 162 includes bump structures 124 outside line 160. Region 166 includes bump structures 124 between line 160 and line 168. Region 170 includes bump structures 124 inside line 168. Regions 162, 166, and 170 are logically organized to have a sufficient number of available leads 142 to accommodate the bump structures within the defined region. Bond wires 148 and 158 are connected to leads 142 and bump structures 124 within region 162, similar to FIG. 7a-7c. The bump continuity test is performed for region 162, as described in FIGS. 6 and 7a-7c. Bond wires 148 are removed and reconnected to leads 142 and bump structures 124 within region 166, similar to FIG. 7a-7c. The bump continuity test is performed for region 166, as described in FIGS. 6 and 7a-7c. Bond wires 148 are removed and reconnected to leads 142 and bump structures 124 within region 170, similar to FIG. 7a-7c. The bump continuity test is performed for region 170, as described in FIGS. 6 and 7a-7c.

In FIG. 9, a smaller electrical component 180 is disposed on paddle 144. In this case, there may be a sufficient number of leads 142 to connect to all bump structures 124. Otherwise, zones or regions would need to be established to perform bump continuity test on electrical component 180, similar to FIG. 8.

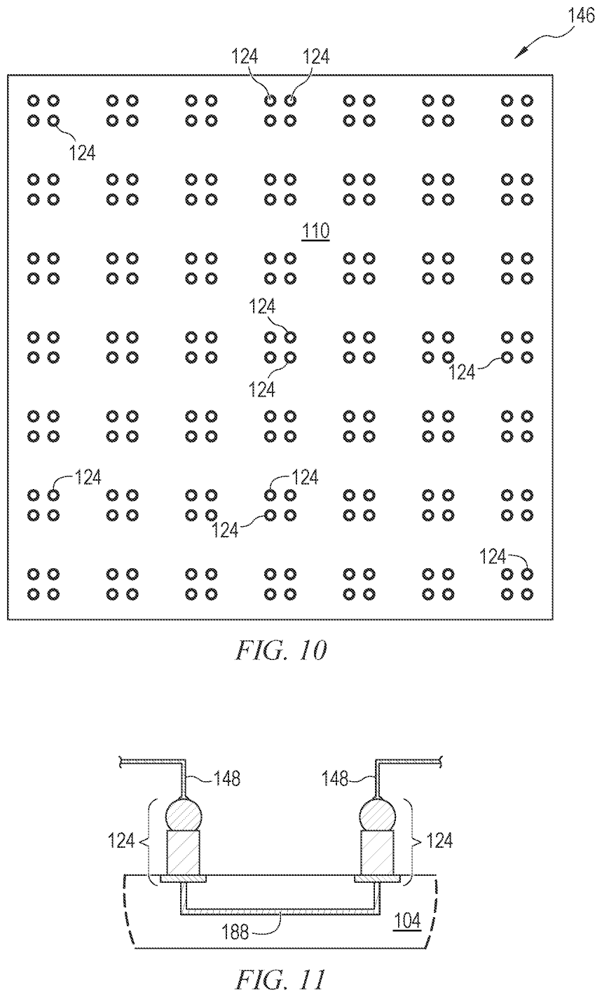

In FIG. 10, after the continuity test, bond wires 148 are removed and conductive segments 130 are cut to physically and electrically isolate bump structures 124 so electrical component 146 can perform its intended electrical function. Conductive segments 130 can be cut by laser or saw. Depending on the normal electrical function of electrical component 146, some or all of conductive segments 130 may remain. Electrical component 146 is removed from lead frame interposer 140 with continuity of bump structures 124 tested and confirmed. Electrical component 146 can be encapsulated with bump structures 124 exposed for further functional probe testing and normal operation.

Lead frame interposer 140 with bond wires 148 and conductive layer 130 provides a cost-effective and efficient means of performing a continuity test of bump structures 124. Bond wire 148 provides flexibility and configurability to route to fine pitch bump structures 124.

In another embodiment, redistribution layer 188 in active surface 110 would provide the electrical connection between bump structures 124a and 124b, as shown in FIG. 11.

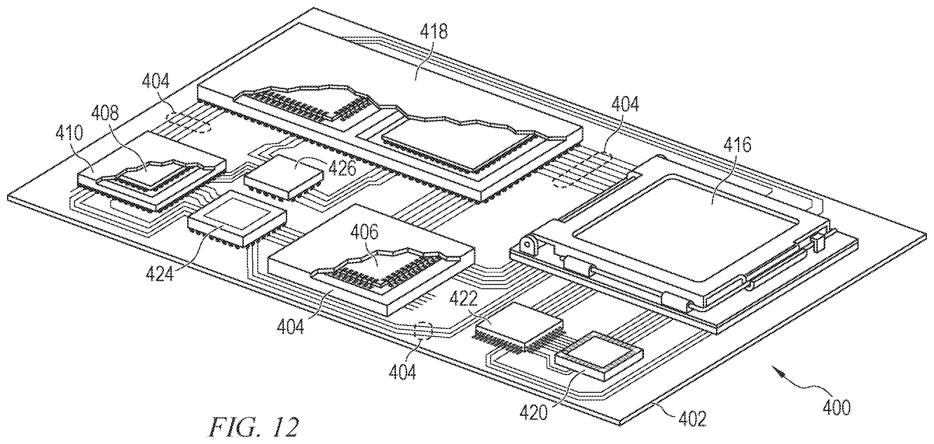

FIG. 12 illustrates electrical device 400 having a chip carrier substrate or PCB 402 with a plurality of semiconductor packages disposed on a surface of PCB 402, including electrical component 146. Electrical device 400 can have one type of semiconductor package, or multiple types of semiconductor packages, depending on the application.

Electrical device 400 can be a stand-alone system that uses the semiconductor packages to perform one or more electrical functions. Alternatively, electrical device 400 can be a subcomponent of a larger system. For example, electrical device 400 can be part of a tablet, cellular phone, digital camera, communication system, or other electrical device. Alternatively, electrical device 400 can be a network interface card, or other signal processing card that can be inserted into a computer. The semiconductor package can include microprocessors, memories, ASIC, logic circuits, analog circuits, RF circuits, discrete devices, or other semiconductor die or electrical components. Miniaturization and weight reduction are essential for the products to be accepted by the market. The distance between semiconductor devices may be decreased to achieve higher density.

In FIG. 12, PCB 402 provides a general substrate for structural support and electrical interconnect of the semiconductor packages disposed on the PCB. Conductive signal traces 404 are formed over a surface or within layers of PCB 402 using evaporation, electrolytic plating, electroless plating, screen printing, or other suitable metal deposition process. Signal traces 404 provide for electrical communication between each of the semiconductor packages, mounted components, and other external system components. Traces 404 also provide power and ground connections to each of the semiconductor packages.

In some embodiments, a semiconductor device has two packaging levels. First level packaging is a technique for mechanically and electrically attaching the semiconductor die to an intermediate substrate. Second level packaging involves mechanically and electrically attaching the intermediate substrate to the PCB. In other embodiments, a semiconductor device may have the first level packaging where the die is mechanically and electrically disposed directly on the PCB. For the purpose of illustration, several types of first level packaging, including bond wire package 406 and flipchip 408, are shown on PCB 402. Additionally, several types of second level packaging, including ball grid array (BGA) 410, bump chip carrier (BCC) 412, land grid array (LGA) 416, multi-chip module (MCM) or SIP module 418, quad flat non-leaded package (QFN) 420, quad flat package 422, embedded wafer level ball grid array (eWLB) 424, and wafer level chip scale package (WLCSP) 426 are shown disposed on PCB 402. In one embodiment, eWLB 424 is a fan-out wafer level package (Fo-WLP) and WLCSP 426 is a fan-in wafer level package (Fi-WLP). Depending upon the system requirements, any combination of semiconductor packages, configured with any combination of first and second level packaging styles, as well as other electrical components, can be connected to PCB 402. In some embodiments, electrical device 400 includes a single attached semiconductor package, while other embodiments call for multiple interconnected packages. By combining one or more semiconductor packages over a single substrate, manufacturers can incorporate pre-made components into electrical devices and systems. Because the semiconductor packages include sophisticated functionality, electrical devices can be manufactured using less expensive components and a streamlined manufacturing process. The resulting devices are less likely to fail and less expensive to manufacture resulting in a lower cost for consumers.

While one or more embodiments of the present invention have been illustrated in detail, the skilled artisan will appreciate that modifications and adaptations to those embodiments may be made without departing from the scope of the present invention as set forth in the following claims.

What is claimed:

1. A semiconductor device, comprising:
an electrical component including a first bump structure and a second bump structure formed over a surface of the electrical component;
a conductive layer formed over the surface of the electrical component with a first segment of the conductive layer electrically coupled between the first bump structure and second bump structure;
a lead frame interposer, wherein the electrical component is disposed on a paddle of the lead frame interposer;
a first bond wire coupled between a first lead of the lead frame interposer and the first bump structure; and
a second bond wire coupled between a second lead of the lead frame interposer and the second bump structure.

2. The semiconductor device of claim 1, further including:
a third bond wire coupled between a third lead of the lead frame interposer and a third bump structure of the electrical component;
a fourth bond wire coupled between a fourth lead of the lead frame interposer and a fourth bump structure of the electrical component; and
a fifth bond wire coupled between the second lead and third lead;
wherein a second segment of the conductive layer is coupled between the third bump structure and fourth bump structure.

3. The semiconductor device of claim 2, wherein a serial combination of the first lead, first bond wire, first bump structure, first segment of the conductive layer, second bump structure, second bond wire, second lead, fifth bond wire, third lead, third bond wire, third bump structure, second segment of the conductive layer, fourth bump structure, fourth bond wire, and fourth lead constitute a daisy chain loop to test continuity of the first bump structure, second bump structure, third bump structure, and fourth bump structure.

4. The semiconductor device of claim 3, further including:
a voltage source coupled to the first lead; and
a current measuring device coupled to the fourth lead to test continuity of the first bump structure, second bump structure, third bump structure, and fourth bump structure.

5. The semiconductor device of claim 1, wherein the first bump structure includes a bump.

6. The semiconductor device of claim 1, wherein the first bump structure includes:
a conductive pillar; and
a bump formed over the conductive pillar.

7. A semiconductor device, comprising:
an electrical component including a plurality of bump structures formed over a surface of the electrical component;
a conductive layer formed over the surface of the electrical component with a first segment of the conductive layer electrically coupled between a first bump structure and a second bump structure of the plurality of bump structures;
a first electrical connection coupled to the first bump structure; and
a second electrical connection coupled to the second bump structure.

8. The semiconductor device of claim 7, further including a lead frame interposer, wherein the electrical component is disposed on a paddle of the lead frame interposer, and the first electrical connection comprises a first bond wire coupled between a first lead of the lead frame interposer and the first bump structure, and the second electrical connection comprises a second bond wire coupled between a second lead of the lead frame interposer and the second bump structure.

9. The semiconductor device of claim 8, further including:
a third bond wire coupled between a third lead of the lead frame interposer and a third bump structure of the plurality of bump structures;
a fourth bond wire coupled between a fourth lead of the lead frame interposer and a fourth bump structure of the plurality of bump structures; and
a fifth bond wire coupled between the second lead and third lead;
wherein a second segment of the conductive layer is coupled between the third bump structure and fourth bump structure.

10. The semiconductor device of claim 9, wherein a serial combination of the first lead, first bond wire, first bump structure, first segment of the conductive layer, second bump structure, second bond wire, second lead, fifth bond wire, third lead, third bond wire, third bump structure, second segment of the conductive layer, fourth bump structure, fourth bond wire, and fourth lead constitute a daisy chain loop to test continuity of the first bump structure, second bump structure, third bump structure, and fourth bump structure.

11. The semiconductor device of claim 10, further including:
a voltage source coupled to the first lead; and
a current measuring device coupled to the fourth lead to test continuity of the first bump structure, second bump structure, third bump structure, and fourth bump structure.

12. The semiconductor device of claim 7, wherein the first bump structure includes a bump.

13. The semiconductor device of claim 7, wherein the first bump structure includes:
a conductive pillar; and
a bump formed over the conductive pillar.

14. A method of making a semiconductor device, comprising:
providing an electrical component including a first bump structure and a second bump structure formed over a surface of the electrical component;
forming a conductive layer over the surface of the electrical component with a first segment of the conductive layer electrically coupled between the first bump structure and second bump structure;
providing a lead frame interposer, wherein the electrical component is disposed on a paddle of the lead frame interposer;
disposing a first bond wire between a first lead of the lead frame interposer and the first bump structure; and
disposing a second bond wire between a second lead of the lead frame interposer and the second bump structure.

15. The method of claim 14, further including:
disposing a third bond wire between a third lead of the lead frame interposer and a third bump structure of the electrical component;
disposing a fourth bond wire between a fourth lead of the lead frame interposer and a fourth bump structure of the electrical component; and
disposing a fifth bond wire between the second lead and third lead;
wherein a second segment of the conductive layer is coupled between the third bump structure and fourth bump structure.

16. The method of claim 15, wherein a serial combination of the first lead, first bond wire, first bump structure, first segment of the conductive layer, second bump structure, second bond wire, second lead, fifth bond wire, third lead, third bond wire, third bump structure, second segment of the conductive layer, fourth bump structure, fourth bond wire, and fourth lead constitute a daisy chain loop to test continuity of the first bump structure, second bump structure, third bump structure, and fourth bump structure.

17. The method of claim 16, further including:
providing a voltage source coupled to the first lead; and
providing a current measuring device coupled to the fourth lead to test continuity of the first bump structure, second bump structure, third bump structure, and fourth bump structure.

18. The method of claim 14, wherein the first bump structure includes forming a bump.

19. The method of claim 14, wherein the first bump structure includes:
forming a conductive pillar; and
forming a bump over the conductive pillar.

20. A method of making a semiconductor device, comprising:
providing an electrical component including a plurality of bump structures formed over a surface of the electrical component;
forming a conductive layer over the surface of the electrical component with a first segment of the conductive layer electrically coupled between a first bump structure and a second bump structure of the plurality of bump structures;
forming a first electrical connection to the first bump structure; and
forming a second electrical connection to the second bump structure.

21. The method of claim 20, further including providing a lead frame interposer, wherein the electrical component is disposed on a paddle of the lead frame interposer, and the first electrical connection comprises a first bond wire coupled between a first lead of the lead frame interposer and the first bump structure, and the second electrical connection comprises a second bond wire coupled between a second lead of the lead frame interposer and the second bump structure.

22. The method of claim 21, further including:
disposing a third bond wire between a third lead of the lead frame interposer and a third bump structure of the plurality of bump structures;
disposing a fourth bond wire between a fourth lead of the lead frame interposer and a fourth bump structure of the plurality of bump structures; and
disposing a fifth bond wire between the second lead and third lead;
wherein a second segment of the conductive layer is coupled between the third bump structure and fourth bump structure.

23. The method of claim 22, wherein a serial combination of the first lead, first bond wire, first bump structure, first segment of the conductive layer, second bump structure, second bond wire, second lead, fifth bond wire, third lead, third bond wire, third bump structure, second segment of the conductive layer, fourth bump structure, fourth bond wire, and fourth lead constitute a daisy chain loop to test continuity of the first bump structure, second bump structure, third bump structure, and fourth bump structure.

24. The method of claim 20, wherein the first bump structure includes forming a bump.

25. The method of claim 20, wherein the first bump structure includes:
forming a conductive pillar; and
forming a bump over the conductive pillar.
